(19) United States
(12) Patent Application Publication
(10) Pub. No.: US 2023/0377935 A1
(43) Pub. Date: Nov. 23, 2023

(54) TEMPORARY BONDING METHOD

(71) Applicant: COMMISSARIAT À L'ÉNERGIE ATOMIQUE ET AUX ÉNERGIES ALTERNATIVES, Paris (FR)

(72) Inventors: Pierre Montmeat, Grenoble (FR); Frank Fournel, Grenoble (FR)

(21) Appl. No.: 18/317,991

(22) Filed: May 16, 2023

(30) Foreign Application Priority Data
May 17, 2022 (FR) 2204676

(51) Int. Cl. H01L 21/683

(52) U.S. Cl. CPC H01L 21/6835; H01L 2221/6839

(57) ABSTRACT

Temporary bonding method comprising the following steps: a) providing a stack comprising successively a substrate of interest, a thermoplastic adhesive and a first temporary substrate, b) positioning a second temporary substrate on the substrate of interest, the first temporary substrate and the second temporary substrate each having a surface area greater than the surface area of the substrate of interest, c) applying a heat treatment at a temperature greater than or equal to the glass transition temperature of the thermoplastic adhesive, by means of which the thermoplastic adhesive forms a lateral band around the substrate of interest and adheres to the first temporary substrate and to the second temporary substrate, d) removing the second temporary substrate, e) attaching the substrate of interest to a frame, by means of an adhesive sheet, f) removing the first temporary substrate and the thermoplastic adhesive.

### CROSS-REFERENCE TO RELATED APPLICATIONS

This application claims priority from French Patent Application No. 2204676 filed on May 17, 2022. The content of this application is incorporated herein by reference in its entirety.

### TECHNICAL FIELD

The present invention relates to the general field of film transfers.

The invention relates to a temporary bonding method.

The invention also relates to a structure comprising a substrate of interest and a temporary substrate.

The invention is particularly advantageous since it makes it possible to easily separate the temporary substrate (the handle) from the thinned substrate of interest.

The invention finds applications in numerous industrial fields, and in particular for manufacturing imagers, microphones or microelectromechanical systems (or MEMs, standing for ‘MicroElectroMechanical systems’).

### PRIOR ART

Currently, producing circuits on thinned plates generally consists of a temporary bonding method wherein a temporary handle is used for thinning and then manipulating the thinned plate.

Conventionally, the temporary bonding method comprises the following steps:
bonding a substrate of interest 10 to a temporary substrate 20 (also referred to as a handle or handle plate) by means of an adhesive 30 (FIG. 1A),
thinning and outlining the substrate of interest 10 to the required geometry and implementing technological steps on the face of the accessible temporary substrate 10 (FIG. 1B),
mounting the assembly thus obtained on a frame 40 by means of an adhesive sheet 50 (FIG. 1C),
removing the temporary substrate 20 and the adhesive 30 (FIG. 1D).

The adhesive sheet 50 used for the mounting on the frame 40 is generally very flexible and can contact the temporary substrate 20 at the outlining of the substrate of interest 10 (as shown on FIG. 1C). This phenomenon is all the more accentuated, the smaller the thickness of the substrate of interest 10 (typically less than 200 μm) and the wider the outlining (typically greater than 0.5 μm).

Removing the temporary substrate 20 then becomes very difficult, or even impossible, because of the presence of these contact zones. It is therefore necessary to provide a very high mechanical dismantling force to be able to remove the temporary substrate 20, which may damage the substrate of interest 10.

Currently, there are no solutions for remedying this problem.

### DISCLOSURE OF THE INVENTION

One purpose of the present invention is to propose a temporary bonding method overcoming the drawbacks of the prior art, and in particular making it possible to easily remove the temporary substrate without damaging the substrate of interest.

For this purpose, the present invention proposes a temporary bonding method comprising the following steps:
providing a stack comprising successively:
a substrate of interest, having a first main face and a second main face,
a thermoplastic adhesive, facing the first main face of the substrate of interest,
a first temporary substrate,
b) positioning a second temporary substrate on the second main face of the substrate of interest, the first temporary substrate and the second temporary substrate each having a surface area greater than the surface area of the substrate of interest,
c) applying a heat treatment at a temperature greater than or equal to the glass transition temperature of the thermoplastic adhesive, by means of which the thermoplastic adhesive forms a lateral band around the substrate of interest and adheres both to the first temporary substrate and to the second temporary substrate, optionally applying a force during step c),
d) removing the second temporary substrate,
e) attaching the substrate of interest to a frame, by means of an adhesive sheet, the adhesive sheet being in contact with the first main face of the substrate of interest,
f) removing the first temporary substrate and the thermoplastic adhesive.

The invention is fundamentally distinguished from the prior art by the formation of an adhesive lateral band around the substrate of interest. This lateral band avoids contact between the adhesive sheet attached to the frame and the first temporary substrate (i.e. the handle), which can therefore be removed easily, without needing to use a high mechanical dismantling force. The substrate of interest is thus preserved, even for very thin substrates (typically less than 200 μm) and/or for large outlining (typically greater than 500 μm).

The formation of the lateral band around the substrate of interest is made possible by means of the use of a first temporary substrate and of a second temporary substrate each having a surface area greater than the surface area of the substrate of interest.

During step c), the thermoplastic adhesive is heated to a temperature above its glass transition temperature, by means of which the thermoplastic adhesive becomes viscous and flows on either side of the substrate of interest until it contacts both the first temporary substrate and the second temporary substrate, thus forming an adhesive lateral band around the substrate of interest. Applying a pressure facilitates the formation of this lateral band.

According to a first advantageous variant embodiment, the glass transition temperature of the thermoplastic adhesive is below 250° C. and preferably below 200° C.

Advantageously, according to this first variant embodiment, the second temporary substrate is made from polytetrafluoroethylene or from polyimide. Alternatively, the second substrate may be covered with a polymer layer of polytetrafluoroethylene or polyimide. The polymer layer is positioned between the second temporary substrate and the substrate of interest.

Advantageously, according to this first variant embodiment, step d) is implemented by a mechanical action, and where applicable the polymer layer covering the second temporary substrate is removed by peeling.

Advantageously, according to this first variant embodiment, during step c), a thermocompression is applied.

According to a second advantageous variant embodiment, the glass transition temperature of the thermoplastic adhesive is above 200° C. and preferably above 250° C., and step b) is preferably implemented by direct bonding.

Advantageously, according to this second variant embodiment, step d) is implemented by mechanical grinding and chemical etching.

Advantageously, according to this second variant embodiment, during step c), a thermocompression is applied.

According to a third advantageous embodiment, a removal of the second substrate by laser can be envisaged. In this case, the second temporary substrate is preferably made from glass or from silicon and is covered by a removal layer sensitive to laser, for example to UV or infrared radiation. The laser-sensitive removal layer is positioned between the second temporary substrate and the substrate of interest.

Advantageously, according to this third variant embodiment, during step c), a thermocompression is applied.

Advantageously, according to this third variant embodiment, step d) is implemented by laser-assisted removal.

Advantageously, the substrate of interest has a surface the largest dimension of which is at least 200 μm, preferably at least 500 μm, and even more preferentially at least 1 cm, less than the largest dimension of the surface of the first temporary substrate and/or the largest dimension of the surface of the second temporary substrate.

Typically, the substrates are slices or wafers (i.e. circular plates) and the largest dimension is the diameter. The lateral band is then in the form of a ring.

It is possible to reduce the dimensions of the substrate of interest during the method (for example after step a).

Advantageously, a removal layer is positioned between the thermoplastic adhesive and the first temporary substrate and/or between the substrate of interest and the second temporary substrate.

The removal layer is preferably made from a fluorinated polymer, for example a fluoroacrylate, or from an organosilica compound such as octadecyltrichlorosilane or perfluorodecyltrichlorosilane.

The method has numerous advantages:
being simple to implement,
being able to be used for numerous materials,
being able to be used for a thin substrate of interest (typically less than 200 μm) and/or for large outlining (typically greater than 0.5 μm).

The invention also relates to a structure consisting successively of:
a substrate of interest, having a first main face and a second main face,
a thermoplastic adhesive, facing the first main face of the substrate of interest,
optionally a removal layer, preferably made from a fluorinated polymer or from an organosilica compound,
a first temporary substrate,
the first temporary substrate having a surface area greater than the surface area of the substrate of interest,
the thermoplastic adhesive forming a lateral band around the substrate of interest.

Other features and advantages of the invention will become apparent from the following additional description.

### BRIEF DESCRIPTION OF THE DRAWINGS

The present invention will be better understood upon reading the description of example embodiments given for purely indicative and non-limiting purposes with reference to the appended drawings wherein:

FIGS. 1A, 1B, 1C and 1D described previously, show, schematically and in cross-section, various steps of a temporary bonding method according to the prior art.

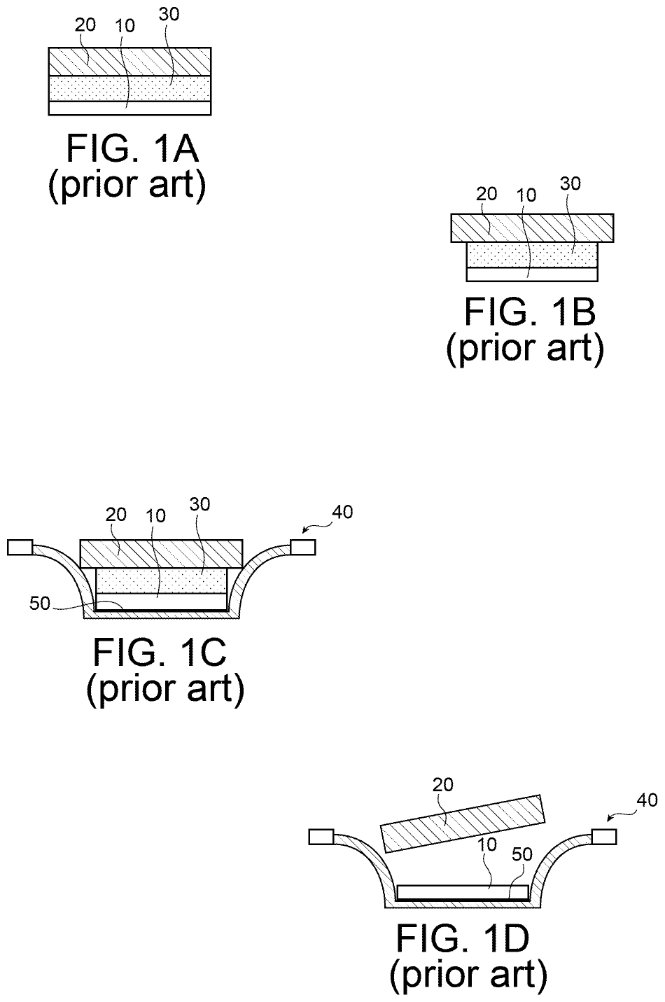

FIGS. 2A to 2F show, schematically and in cross-section, various steps of a temporary bonding method according to a particular embodiment of the invention,

FIGS. 3A to 3F show, schematically and in cross-section, various steps of a temporary bonding method according to another particular embodiment of the invention.

The various parts shown in the figures are not necessarily shown to a uniform scale, to make the figures more readable.

The various possibilities (alternatives and embodiments) must be understood as not being mutually exclusive and can be combined with one another.

Moreover, in the description below, the terms that depend on the orientation, such as “above”, “below”, etc. of a structure apply for a structure that is considered to be oriented in the manner illustrated in the figures.

### DETAILED DESCRIPTION OF SPECIFIC EMBODIMENTS

Although this is by no means limiting, the invention particularly has applications in the microelectronics field. In particular, the invention is advantageous for manufacturing transistors, imagers, microelectromechanical systems (or MEMs, standing for ‘MicroElectroMechanical systems’) or microphones.

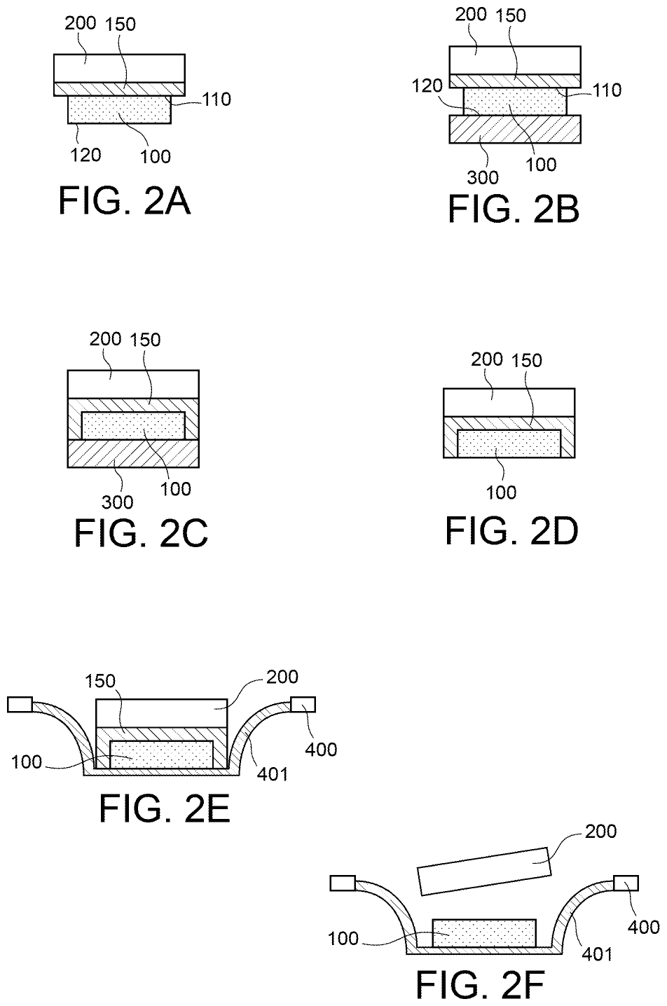

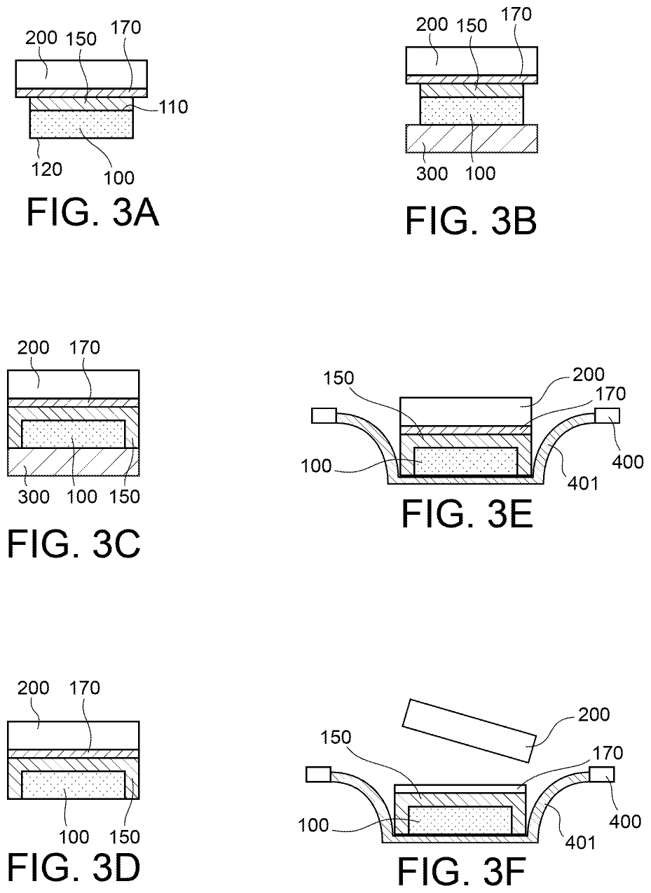

Referring to FIGS. 2A to 2F, or to FIGS. 3A and 3F, we shall now describe in more detail various variants of a temporary bonding method according to the invention.

The temporary bonding method comprising at least the following steps:
providing a stack comprising successively (FIG. 2A or FIG. 3A):
a substrate of interest 100, having a first main face 110 and a second main face 120,
a thermoplastic adhesive 150, facing the first main face 110 of the substrate of interest 100,
a first temporary substrate 200,
b) positioning a second temporary substrate 300 on the second main face 120 of the substrate of interest 100, the first temporary substrate 200 and the second temporary substrate 300 each having a surface area greater than the surface area of the substrate of interest 100 (FIG. 2B or FIG. 3B),
c) applying a heat treatment at a temperature greater than or equal to the glass transition temperature of the thermoplastic adhesive 150, optionally applying a force, by means of which the thermoplastic adhesive 150 forms a lateral band around the substrate of interest 100 and adheres both to the first temporary substrate 200 and to the second temporary substrate 300 (FIG. 2C or FIG. 3C),
d) removing the second temporary substrate 300 (FIG. 2D or FIG. 3D),
e) attaching the substrate of interest 100 to a frame 400, by means of an adhesive sheet 401, the adhesive sheet 401 being in contact with the second main face 120 of the substrate of interest 100 (FIG. 2E or FIG. 3E),
f) removing the second temporary substrate 200 and the thermoplastic adhesive 150 (FIG. 2F or FIG. 3F).

Step a) can be implemented in accordance with the following substeps:
attaching a first temporary substrate 200 to the first main face 110 of the substrate of interest 100, by means of a thermoplastic adhesive,
optionally, implementing a heat treatment.

The substrate of interest 100 comprises a first main face 110 having a first surface and a second main face 120 having a second surface, parallel or substantially parallel to each other. A lateral face with a thickness e goes from the first main face 110 to the second main face 120 of the substrate of interest 100. The first surface of the first main face 110 and the second surface of the second main face 120 have the same surface, referred to as the surface of the substrate of interest.

The first temporary substrate 200 comprises a first main face and a second main face. The first main face of the first temporary substrate is facing the first main face 110 of the substrate of interest 100.

The first main face 110 of the substrate of interest is advantageously covered by components.

The manufacture of these components may include for example steps of lithography, ion etching, depositions, polishing or implantation. On one and the same main face of the substrate of interest, the components may be identical or different.

The thermoplastic adhesive 150 is for example in the form of an adhesive film.

The thermoplastic adhesive 150 preferably covers the entire surface of the first face 110 of the substrate of interest 100.

The thermoplastic adhesive 150 is made from thermoplastic material. The product Brewer 305 sold by Brewer Science or TOK Zero Newton TWN12000 sold by TOKYO OHKA KOGYO Co. will for example be selected.

The thickness of the adhesive film 150 is, for example, between 1 μm and 200 mm, and preferably between 20 μm and 100 mm. The thickness of the adhesive film depends on the volume delimited by the lateral wall of the substrate of interest 100, the first temporary substrate 200 and the second temporary substrate 300.

According to a particular embodiment, a removal layer 170 (also called a bonding layer) may be disposed between the thermoplastic adhesive 150 and the first temporary substrate 200 (FIG. 3A).

The removal layer 170 is intended to facilitate the removal of the first substrate. It may be made from an organosilica compound having at least one chlorine atom such as octadecyltrichlorosilane (OTS), perfluorodecyltrichlorosilane (FDTS), or perfluorodecyldimethylchlorosilane (FDDMCS).

Organosilica compound means a compound having at least one carbon-silicon bond.

The removal layer 170 may be a fluorinated polymer, such as a fluoroacrylate or a polymer of the fluorosilane type. The fluorinated polymers sold by the 3M company under the reference Novec™ 2702, Novec™ 1700 or Novec™ 1720 or the fluorinated polymers sold by the company Daikin under the reference Optool™ will for example be selected.

The thickness of the removal layer 170 is, for example, between 1 nm and 1 μm, and preferably between 5 nm and 100 nm.

According to this particular embodiment, when the removal layer 170 is positioned between the first temporary substrate 200 and the substrate of interest, step a) of the method may comprise the following substeps:
depositing a removal layer 170 on the first temporary substrate 200,
positioning a thermoplastic adhesive 150 between the first main face 110 of the substrate of interest 100 and the first temporary substrate 200, and more particularly between the first main face 110 of the substrate of interest 100 and the removal layer 170,
implementing a heat treatment.

The removal layer 170 partially covers, and preferably completely covers, the first temporary substrate 200.

Between step a) and step b), the method may comprise a step during which the substrate of interest 100 is thinned and/or components are manufactured on the second main face 120 of the substrate of interest 100. The components on the second main face 120 may be identical to or different from those present on the first main face 110.

During step b), a second temporary substrate 300 is positioned on the exposed face (the second main face 120) of the substrate of interest 100.

According to a variant embodiment that is not shown, another removal layer may be positioned between the substrate of interest 100 and the second temporary substrate 300.

The second temporary substrate 300 comprises a first main face and a second main face. The first main face of the second temporary substrate 300 is facing the second main face 120 of the substrate of interest 100.

The substrate of interest 100, the first temporary substrate 200 and the second temporary substrate 300 are for example circular plates.

The substrate of interest 100 is made from a first material, the first temporary substrate 200 is made from a second material and the second temporary substrate 300 is made from a third material.

The first material, the second material and the third material may be identical or different.

The first material, the second material and the third material are independently selected from semiconductor materials, for example silicon or germanium, silica, glass, sapphire, ceramics, for example SiC, III-V materials such as AsGa, GaN or InP, piezoelectric materials such as LNO/LTO or metals (for example molybdenum, tungsten, titanium, platinum or copper) or alloys. For example, the first material, the second material and the third material may be silicon.

The first temporary substrate 200 and the second temporary substrate 300 each have a surface area greater than the surface area of the substrate of interest 100.

The first temporary substrate 200 and the second temporary substrate 300 preferably have the same surface area.

The width of the outlining of the substrate of interest 100 is advantageously larger than or equal to 200 μm and preferably larger than or equal to 500 μm). The outlining depends on the size of the substrate of interest 100. For a circular substrate with a diameter of 300 mm, an outlining of 1 cm can for example be selected. For a smaller substrate of 50 mm, an outlining of between 100 μm and 1 mm is suitable.

Advantageously, step c) is performed using a heat treatment, by means of which the adhesive film 150 becomes viscous, flows on either side of the substrate of interest 100 and forms a lateral band around the substrate of interest 100 and adheres both to the first temporary substrate 200 and to the second temporary substrate 300. At this step, it is considered that the viscosity of the thermoplastic adhesive must be less than or equal to 10⁴ Pa·s to obtain good flow.

The lateral band is continuous from the first temporary substrate 200 as far as the second temporary substrate 300. The lateral band is preferably in contact with the lateral wall (also called the flank) of the substrate of interest 100. Alternatively, the lateral band may not be in contact with the lateral wall of the substrate of interest 100 (i.e. a void may be present between the lateral wall of the substrate of interest and the lateral band).

During step c), a temperature will be applied, sufficiently high for the assembly. In particular, a temperature higher than the glass transition temperature Tg will be applied (for example a temperature T such that T>Tg+100° C.), so that the adhesive becomes sufficiently fluid, flows and fills in the outlined space. For example, advantageously, a temperature will be selected such that the viscosity of the adhesive is less than 10⁴ Pa·s.

Advantageously, a force will also be applied during step c). The force will be sufficiently high. For example, it will be possible to apply a force greater than or equal to 20 kN in the case of a substrate 300 mm in diameter and to use a temperature greater than or equal to 200° C.

At the end of step c) the adhesive film 150 forms a lateral band around the substrate of interest 100 and adheres both to the first temporary substrate 200 and to the second temporary substrate 300.

The adhesion energy E₁ between the substrate of interest 100, and the first temporary substrate 200 is greater than the adhesion energy E₂ between the substrate of interest 100 and the second temporary substrate 300.

The adhesion E₃ between the two temporary substrates can be broken down into two adhesions E₃₁ and E₃₂ respectively between the first temporary substrate and the adhesive band and between the second temporary substrate and the adhesive band. The adhesion energy E₃₁ between the first temporary substrate 200 and the adhesive is greater than the adhesion energy E₃₂ between the second temporary substrate 300 and the adhesive.

In step d), the second temporary substrate 300 is separated from the structure comprising the substrate of interest 100, the thermoplastic adhesive 150, optionally the removal layer 170, and the first temporary substrate 200.

In step e), this structure is mounted on a frame 400 by means of an adhesive sheet (or adhesive film) 401. No contact is possible between the adhesive sheet 401 and the first temporary substrate 200. The frame 400 is for example a circular frame.

The frame 400 may be a metal frame, for example of the ‘DISCO’ type.

The adhesive layer 401, used during step e), making it possible to hold the stack on the frame 400, is for example an acrylic layer.

The thickness of the adhesive layer 401 is, for example, between 50 μm and 150 mm.

The face of the adhesive layer 401 that is not in contact with the assembly may be covered by a non-adhesive film, for example made from polyethylene terephthalate (PET) or from polypropylene.

An adhesive layer 401 sold by the company Furukawa® under the reference SP-537T-230 will for example be selected.

In step f), the first temporary substrate 200 and the thermoplastic adhesive 150 are removed. Where applicable, the removal layer 170 is also removed.

The thermoplastic adhesive 150 can be removed by cleaning by means of an adapted solvent. The solvent is for example selected from alcohols and hydrocarbons, or one of the mixtures thereof. By way of illustration, a first cleaning based on D-limonene followed by rinsing based on isopropyl alcohol (also called propan-2-ol) can be selected. It is also possible to use mesitylene.

Three variant embodiments that can be implemented will now be described in more detail.

According to a first variant embodiment, the flow temperature of the thermoplastic adhesive 150 is below 250° C., or even below 200° C. It will then be possible to use a second temporary substrate 300 made from a non-adhesive organic compound, for example made from fluorinated polymer, preferably from polytetrafluoroethylene (also known by the commercial reference Teflon®) or from polyimide (also known by the commercial reference Kapton®). Alternatively, it is possible to use a second temporary substrate 300, for example a silicon wafer, covered by a non-adhesive layer, for example made from polytetrafluoroethylene or from polyimide. Step c) is then implemented by means of thermocompression.

According to this first variant embodiment, step d) can be implemented by removing just the second temporary substrate 300 by a mechanical removal. If the second temporary substrate 300 comprises a non-adhesive layer, the latter can be removed by peeling.

According to a second advantageous variant embodiment, the flow temperature of the thermoplastic adhesive is below 200° C., or even below 200° C. Step b) is advantageously implemented by means of direct gluing, for example of the Si/SiO₂ type. Step c) is implemented by means of thermocompression.

According to this second variant embodiment, step d) can be implemented by mechanical grinding and chemical etching.

Preferably, the second temporary substrate 300 is made from silicon. It is then for example possible to use a first HF/HNO₃ chemical etching solution for the silicon and then a second chemical etching solution based on HF.

A first temporary substrate 200 made from glass will for example be selected.

According to a third variant embodiment, the second temporary substrate 300 is made from glass and is covered by a removal layer sensitive to laser radiation. A removal layer made from BrewerBond 701 will for example be used. Step c) is then implemented by thermocompression, by means of which the substrate of interest 100 and the second temporary substrate 300 are secured to each other. The temperature of the thermocompression depends on the strength of the removal layer and on the flow temperature of the adhesive.

According to this third variant embodiment, step d) can be implemented by removing the glass plate 300 by laser-assisted removal.

### Illustrative and Non-Limiting Examples of One Embodiment

Various example embodiments will now be described in more detail.

### Example 1: 1st Variant Embodiment: Second Temporary Substrate 300 Made from a Non-Adhesive Organic Compound (Teflon®)

Silicon wafers 200 mm in diameter will be used as substrate of interest 100 and as first temporary substrate 200.

On the first temporary substrate 200 made from silicon, a removal layer 170 is spread. This is a film of Novec™ 2702 and the assembly is annealed at 150° C. for 30 min.

By means of a diamond saw, the substrate of interest 100 made from silicon is outlined over a width of 1.5 mm and a depth of 200 μm. 40 μm of a thermoplastic adhesive 150 is spread on this wafer 100. This is a Brewer 305 adhesive resin. This assembly is bonded at 210° C. with the first temporary substrate 200 so as to create an interface between the thermoplastic adhesive 150 and the removal layer 170.

The substrate of interest 100 is thinned to 20 μm by mechanical abrasion by means of a diamond wheel. The surface of the substrate of interest 100 undergoes wet cleaning. Then the assembly is mounted on a “DISCO” metal frame 400 by means of a Furukawa® SP-537T-230 adhesive sheet 401. The adhesive sheet 401 contacts the first temporary substrate 200 and mechanical removal of this temporary substrate 200 is impossible.

Alternatively, a second Teflon temporary substrate 300 200 mm in diameter and 3 mm thick is bonded with the substrate of interest 100 by thermocompression. The bonding is implemented at 200° C. at a force of 20 kN. By inserting a wedge in this stack, the second temporary substrate 300 is next removed.

The assembly is mounted on a “DISCO” metal frame 400 by means of a Furukawa® SP-537T-230 adhesive sheet 401. The adhesive sheet 401 does not contact the first temporary substrate 200 and mechanical removal of this temporary substrate 200 is possible. The Brewer 305 adhesive resin is removed by cleaning based on D-limonene and isopropanol.

### Example 2: 1st Variant Embodiment: Second Temporary Substrate 300 Covered by a Layer of Fluorinated Polymer

The temporary substrate 200 and 300 and the substrate of interest 100 are silicon wafers 200 mm in diameter.

On the first temporary substrate 200, a removal layer 170 (film of Novec™ 2702) is spread and the assembly is annealed at 150° C. for 30 min.

By means of a diamond saw, the substrate of interest is outlined over a width of 1.5 mm and a depth of 200 μm. 40 μm of a thermoplastic adhesive 150 (Brewer 305 adhesive resin) is spread on the substrate of interest 100 and this assembly is bonded at 210° C. with the first temporary substrate 200 so as to create an interface between the thermoplastic adhesive 150 and the removal layer.

The substrate of interest 100 is thinned to 20 μm by mechanical abrasion by means of a diamond wheel. The surface of the substrate of interest 100 undergoes wet cleaning. A fluorinated film of Daikin Optool™ is spread on the second temporary substrate 300. The second temporary substrate 300 is bonded with the first temporary substrate 200 by thermocompression so as to create an interface between the film of Optool™ and the surface of the substrate of interest 100. The bonding is implemented at 200° C. at a force of 20 kN. By inserting a wedge in this stack, the second temporary substrate 300 is removed.

The assembly is mounted on a “DISCO” metal frame 400 by means of a Furukawa® SP-537T-230 adhesive film 401. The adhesive film 401 does not contact the first temporary substrate 200 and mechanical removal of this temporary substrate is possible. The Brewer 305 adhesive resin is removed by cleaning based on D-limonene and isopropanol.

### Example 3: 1st Variant Embodiment: Second Temporary Substrate 300 Covered by a Non-Adhesive Organic Compound of the Kapton® Type

Silicon wafers 200 mm in diameter are used for the temporary substrates 200 and 300 and for the substrate of interest 100.

On the first temporary substrate 200, a removal layer 170 (film of Novec™ 2702) is spread and the assembly is annealed at 150° C. for 30 min.

By means of a diamond saw, the temporary substrate 100 is outlined over a width of 1.5 mm and a depth of 200 μm. 40 μm of a thermoplastic adhesive 150 (Brewer 305 adhesive resin) is spread on this way for and this assembly is bonded at 210° C. with the first temporary substrate 200 so as to create an interface between the thermoplastic adhesive 150 and the removal layer 170.

The substrate of interest 100 is thinned to 20 μm by mechanical abrasion by means of a diamond wheel. The surface of this substrate undergoes wet cleaning.

Bonding by thermocompression of the following stack is implemented: the second temporary substrate 300/a sheet of Kapton® (Upilex 25S)/the substrate of interest 100/the thermoplastic adhesive 150/the removal layer/the first temporary substrate 200. An interface is produced between the substrate of interest 100 and the Upilex sheet. The bonding is implemented at 200° C. at a force of 20 kN. By inserting a wedge in this stack, the second temporary substrate 300 is next removed and the Upilex sheet is peeled from the substrate of interest 100.

The assembly is mounted on a “DISCO” metal frame 400 by means of a Furukawa® SP-537T-230 adhesive sheet 401. The adhesive film does not contact the first temporary substrate 200 and mechanical removal of this temporary substrate is possible. The Brewer 305 adhesive resin is removed by cleaning based on D-limonene and isopropanol.

### Example 4: 2nd Variant Embodiment: Second Temporary Substrate 300 Made from Silicon Assembled by Direct Bonding to the Substrate of Interest 100

Use is made for the substrate of interest 100 and the second temporary substrate 200 are silicon wafers 200 mm in diameter.

By means of a diamond saw, the substrate of interest 100 is outlined over a width of 0.5 mm and a depth of 200 μm. 20 μm of a thermoplastic adhesive 150 (HD3007 adhesive resin) is spread on this wafer 100 and this assembly is bonded at 350° C. with a first temporary substrate 200. The first temporary substrate 200 is a glass plate.

The substrate of interest 100 is thinned to 20 μm by mechanical abrasion by means of a diamond wheel. The surface of this substrate 100 undergoes wet cleaning and chemical mechanical polishing.

A silicon wafer (second temporary substrate 300) is oxidised so as to form on the surface a film of SiO₂ of 400 nm. An Si/SiO₂ direct bonding is implemented between the second temporary substrate 300 and the polished face of the substrate of interest 100. This stack undergoes annealing at 380° C. at a force of 10 kN. By mechanical abrasion, the thickness of the second temporary substrate 300 is reduced to 50 μm. The remaining silicon is next etched by a solution of HF/HNO₃, the 400 nm layer of SiO₂ constitutes a stop layer for the etching of the silicon. This layer of SiO₂ is removed by etching based on HF. This etching stops on the silicon of the substrate of interest 100 and on the thermoplastic adhesive 150 (HD3007 resin).

The assembly is mounted on a “DISCO” metal frame 400 by means of a Furukawa® SP-537T-230 adhesive film 401. The glass first temporary substrate 200 is irradiated by means of a 248 nm laser. This treatment degrades the interface between the glass and the HD 3007 adhesive. The adhesive film 401 does not contact the second temporary substrate 200 and mechanical removal of this temporary substrate 200 is possible. The HD3007 adhesive resin is removed by cleaning based on EKC865.

### Example 5: 3rd Variant Embodiment: Second Glass Temporary Substrate 300 Covered by a Layer Sensitive to Laser Radiation

Silicon wafers 300 mm in diameter are used for the first temporary substrate 200 and for the substrate of interest 100.

On the first temporary substrate 200 made from silicon, a removal layer 170 is spread: a film of OTS (octadecyltrichlorosilane) in solution in isooctane.

By means of a diamond saw, the substrate of interest 100 made from silicon is outlined over a width of 0.5 mm and a depth of 200 μm. A TOK Zero Newton TWM12000 100 μm thermoplastic adhesive film 150 is spread on the substrate of interest 100 and this assembly is bonded at 180° C. with the first temporary substrate 200.

The substrate of interest 100 is thinned to 50 μm by mechanical abrasion by means of a diamond wheel. The surface of the substrate of interest 100 undergoes wet cleaning.

Another adhesive layer (80 nm of a layer of BrewerBOND 701) is spread on the second temporary substrate 300. The second temporary substrate 300 is a glass plate. Bonding by thermocompression is implemented between the surface of the substrate of interest 100 and of the second temporary substrate 300. The bonding is implemented at 240° C. at a force of 15 kN. The second glass temporary substrate 300 is irradiated by means of a 355 nm laser. This treatment degrades the interface between the glass and the BrewerBOND 701 layer. The second temporary substrate 300 is removed mechanically.

The assembly is mounted on a “DISCO” metal frame 400 by means of a Furukawa® SP-537T-230 adhesive film. The adhesive film does not contact the first temporary substrate 200 and mechanical removal of this temporary substrate 200 is possible. The TOK adhesive resin is removed by cleaning based on mesitylene.

1. Temporary bonding method comprising the following steps:
a) providing a stack comprising successively:
a substrate of interest, having a first main face and a second main face,
a thermoplastic adhesive, facing the first main face of the substrate of interest,
a first temporary substrate,
b) positioning a second temporary substrate facing the second main face of the substrate of interest, the first temporary substrate and the second temporary substrate each having a surface area greater than the surface area of the substrate of interest,
c) applying a heat treatment at a temperature greater than or equal to the glass transition temperature of the thermoplastic adhesive, by means of which the thermoplastic adhesive forms a lateral band around the substrate of interest and adheres both to the first temporary substrate and to the second temporary substrate,
d) removing the second temporary substrate,
e) attaching the substrate of interest to a frame, by means of an adhesive sheet, the adhesive sheet being in contact with the second main face of the substrate of interest,
f) removing the first temporary substrate and the thermoplastic adhesive.

2. Method according to claim 1, wherein the glass transition temperature of the thermoplastic adhesive is below 250° C.

3. Method according to claim 2, wherein the second temporary substrate is made from polytetrafluoroethylene or from polyimide or wherein the second temporary substrate is covered with a polymer layer of polytetrafluoroethylene or of polyimide.

4. Method according to claim 2, wherein step d) is implemented by a mechanical action, and where applicable the polymer layer covering the second temporary substrate is removed by peeling.

5. Method according to claim 1, wherein the glass transition temperature of the thermoplastic adhesive is above 200° C. and wherein step b) is implemented by direct bonding.

6. Method according to claim 5, wherein step d) is implemented by mechanical grinding and chemical etching.

7. Method according to claim 1, wherein the second temporary substrate is made from glass and in that it is covered by a laser-sensitive removal layer.

8. Method according to claim 7, wherein step d) is implemented by laser-assisted removal.

9. Method according to claim 1, wherein, in step c), thermocompression is applied.

10. Method according to claim 1, wherein the substrate of interest has a surface the largest dimension of which is at least 200 μm less than the largest dimension of the surface of the first temporary substrate or the largest dimension of the surface of the second temporary substrate.

11. Method according to claim 1, wherein a removal layer is positioned between the thermoplastic adhesive and the first temporary substrate or between the substrate of interest and the second temporary substrate.

12. Method according to claim 11, wherein the removal layer is made from fluorinated polymer or from an organosilica compound.

13. Structure consisting successively of:
a substrate of interest,
a thermoplastic adhesive,
a first temporary substrate,
wherein the first temporary substrate has a surface area greater than the surface area of the substrate of interest,
and wherein the thermoplastic adhesive forms a lateral band around the substrate of interest.

14. Structure according to claim 13, wherein the substrate of interest is made from a material selected from semiconductor materials, silica, glass, sapphire, ceramics, III-V materials, piezoelectric materials, metals or alloys.

15. Structure consisting successively of:
a substrate of interest,
a thermoplastic adhesive,
a removal layer made from a fluorinated polymer or from an organosilica compound,
a first temporary substrate,
wherein the first temporary substrate has a surface area greater than the surface area of the substrate of interest,
and wherein the thermoplastic adhesive forms a lateral band around the substrate of interest.

16. Structure according to claim 15, wherein the substrate of interest is made from a material selected from semiconductor materials, silica, glass, sapphire, ceramics, III-V materials, piezoelectric materials, metals or alloys.
